(19) United States
(12) Patent Application Publication
(10) Pub. No.: US 2006/0196420 A1
(43) Pub. Date: Sep. 7, 2006

(54) High density plasma chemical vapor deposition apparatus

(76) Inventors: Andrey Ushakov, Suwon-si (KR); Jin Hyuk Choi, Suwon-si (KR); Jong Rok Park, Seoul (KR)

Correspondence Address: STANZIONE & KIM, LLP, 919 18TH STREET, N.W., SUITE 440, WASHINGTON, DC, 20006, US

(21) Appl. No.: 11/246,252

(22) Filed: Oct. 11, 2005

(30) Foreign Application Priority Data
Mar. 2, 2005 (KR) 2005-17420

(51) Int. Cl. C23C 14/00; C23C 16/00

(52) U.S. Cl. 118/715; 118/50

(57) ABSTRACT

A high density plasma chemical vapor deposition apparatus includes an upper gas supply nozzle which includes a nozzle body, a gas supply passage formed vertically in the nozzle body, a nozzle cover attached to a lower surface of the horizontal portion of the nozzle body, and a plurality of gas inlets formed through the nozzle cover to uniformly supply the processing gas towards a semiconductor wafer within the processing chamber.

### CROSS-REFERENCE TO RELATED APPLICATIONS

This application claims the benefit of Korean Patent Application No. 2005-17420, filed on Mar. 2, 2005 in the Korean Intellectual Property Office, the disclosure of which is incorporated herein in its entirety by reference.

### BACKGROUND OF THE INVENTION

1. Field of the Invention

The present general inventive concept relates to a high density plasma chemical vapor deposition apparatus, and more particularly, to a high density plasma chemical vapor deposition apparatus which has a gas supply nozzle enhanced in structure such that processing gas supplied to a semiconductor wafer is uniformly injected from the gas supply nozzle.

2. Description of the Related Art

Chemical vapor deposition (CVD) is one form of semiconductor processing technology, and refers to a process for forming a semiconductor film or an insulating film of a single crystal on a surface of a wafer by use of a chemical reaction. When performing the CVD, it is necessary to perform a heat treatment for the wafer at a high temperature after deposition, which entails an unwanted side effect of semiconductor diode deterioration due to the high temperature. Additionally, since semiconductor diodes are highly integrated, and a gap between metallic wires has become fine as a result of rapid development in semiconductor manufacturing technologies, the CVD has limitations in filling the gap between the metallic wires.

Accordingly, methods for forming an interlayer dielectric layer have been developed which can maximize a capability of filling the gap between the metallic wires, and one of the methods is high density plasma deposition CVD (HDP CVD). The HDP CVD is a process for depositing a dielectric layer on a wafer by generating high density plasma ions and decomposing a source gas through application of an electric field and a magnetic field so as to provide higher ionization efficiency as compared with a conventional CVD (PE CVD). In the HDP CVD, source power for generating the plasma and bias power for etching the interlayer dielectric layer deposited on the wafer are applied simultaneously while the interlayer dielectric layer is deposited on the wafer, thereby allowing the deposition of the interlayer dielectric layer and sputtering etching to be performed at the same time.

When performing these processes, processing gas supplied to a reaction chamber must be uniformly distributed around the wafer in order to provide uniform deposition and an excellent film thereby on the surface of the wafer. Moreover, when performing an etching process, the processing gas must be uniformly distributed around the wafer in order to provide uniform sputtering on the entire surface of the wafer, whereby a desired etching process can be performed.

However, since these processes are performed at a very low pressure of about 3˜10 mTorr, the distribution of the processing gas within the reaction chamber is very sensitively varied, and thus, in order to force the processing gas to be uniformly distributed around the wafer, it is necessary to provide a gas distributing device having a precise design.

With regard to the gas distributing device, U.S. Pat. No. 6,486,081 discloses an installation structure of a conventional gas distributing device for supplying processing gas into an HDP CVD processing chamber. The conventional gas distributing device disclosed therein comprises a plurality of side gas supply nozzles equipped around a side of the processing chamber to supply the processing gas to the processing chamber, and an upper gas supply nozzle equipped at an upper center of the processing chamber to supply the processing gas to an upper portion of the processing chamber. The plurality of side gas supply nozzles comprises first and second gas supply nozzles respectively connected to first and gas supply sources so as to supply first and second processing gases into the processing chamber. The upper gas supply nozzle comprises third and fourth gas supply paths respectively connected to third and fourth gas supply sources so as to supply third and fourth processing gases into the processing chamber.

However, in the conventional gas distributing device, the upper gas supply nozzle for supplying the processing gases to the processing chamber has a single injection port formed in the vertical direction, so that the processing gases supplied through the upper gas supply nozzle are concentrated relatively on the center of the wafer, thereby limiting uniform deposition on the entire surface of the wafer. Moreover, even if the side gas supply nozzles are used to enhance uniformity of a film, there is a problem in that the processing gases injected from the side gas supply nozzles are not delivered to a portion spaced about 5˜7 cm or more from an edge of the wafer.

Moreover, since next generation semiconductor technologies require a wafer having a diameter of 300 mm instead of a wafer having a diameter of 200 mm, if the conventional gas supplying device is applied to such a large size wafer, non-uniform deposition between the center of the wafer directly affected by the upper gas supply nozzle or the edge of the wafer affected by the side gas supply nozzles and a portion of the wafer between the center and the edge of the wafer becomes serious.

### SUMMARY OF THE INVENTION

The present general inventive concept provides a high density plasma chemical vapor deposition apparatus, designed to provide uniform distribution of a processing gas supplied from a gas supply nozzle to a reaction region on a semiconductor wafer, thereby allowing a desired process to be uniformly performed.

Additional aspects of the present general inventive concept will be set forth in part in the description which follows and, in part, will be obvious from the description, or may be learned by practice of the general inventive concept.

The foregoing and/or other aspects of the present general inventive concept may be achieved by providing a high density plasma chemical vapor deposition apparatus comprising a processing chamber having a chamber body and a chamber cover, and an upper gas supply nozzle provided at an upper portion of the processing chamber to supply a processing gas into the processing chamber, the upper gas supply nozzle including a nozzle body including a plate-shaped horizontal portion and a vertical portion extending upward from the horizontal portion, a gas supply passage formed vertically in the nozzle body, a nozzle cover attached to a lower surface of the horizontal portion of the nozzle body, and a plurality of gas inlets formed in the nozzle cover to uniformly supply the processing gas over a semiconductor wafer within the processing chamber.

The nozzle cover may include a cover bottom, and a conical cover side wall extending at a predetermined angle from the cover bottom, and the plurality of gas inlets may be circumferentially formed on the cover side wall to radially inject the processing gas onto the semiconductor wafer.

The upper gas supply nozzle may further include a nozzle cap attached to a central lower surface of the nozzle cover.

When the upper gas supply nozzle further includes the nozzle cap, the cover bottom may be formed with a cover passage passing through the cover bottom to be coaxial with the gas supply passage, and the nozzle cap may be formed with a plurality of gas inlets inclined at a predetermined angle to the horizontal direction while communicating with the cover passage such that the processing gas is supplied to a central region of the semiconductor wafer through the gas inlets formed through the nozzle cap in addition to the gas inlets formed through the cover side wall.

The nozzle cover may have a bottom surface with a convexly spherical shape, that is, a shower head shape, or with a flat disk shape, and may have a plurality of rows of gas inlets inclined at the predetermined angle to the horizontal direction while being provided in a radial direction from a central axis of the nozzle cover to uniformly inject the processing gas to the central region adjacent to a center of the semiconductor wafer.

When the nozzle cover has the plurality of rows of gas inlets formed in the radial direction from the central axis of the nozzle cover, diameters of the gas inlets or angles of the gas inlets inclined with respect to the vertical direction may gradually increase as a distance from a respective gas inlet and the central axis of the nozzle cover increases, to uniformly and effectively distribute the processing gas.

The gas supply passage may include a first supply passage and a second supply passage separated into inner and outer passages by an intermediate member such that different processing gases are supplied into the processing chamber through the first and second supply passages.

### BRIEF DESCRIPTION OF THE DRAWINGS

These and/or other aspects of the present general inventive concept will become apparent and more readily appreciated from the following description of the embodiments, taken in conjunction with the accompanying drawings, of which:

FIG. 1 is a cross-sectional view illustrating a high density plasma chemical vapor deposition apparatus according to an embodiment of the present general inventive concept;

FIG. 2 is a top view illustrating a semiconductor wafer of FIG. 1;

FIG. 3 is a cross-sectional view illustrating an upper gas supply nozzle of a high density plasma chemical vapor deposition apparatus according to an embodiment of the present general inventive concept;

FIG. 4 is a cross-sectional view illustrating an upper gas supply nozzle of a high density plasma chemical vapor deposition apparatus according to another embodiment of the present general inventive concept;

FIG. 5 is a cross-sectional view illustrating an upper gas supply nozzle of a high density plasma chemical vapor deposition apparatus according to another embodiment of the present general inventive concept;

FIG. 6 is a cross-sectional view illustrating an upper gas supply nozzle of a high density plasma chemical vapor deposition apparatus according to another embodiment of the present general inventive concept; and

FIG. 7 is a cross-sectional view illustrating an upper gas supply nozzle of a high density plasma chemical vapor deposition apparatus according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings wherein like reference numerals refer to the like elements throughout the drawings. The embodiments are described below to explain the present general inventive concept while referring to the drawings.

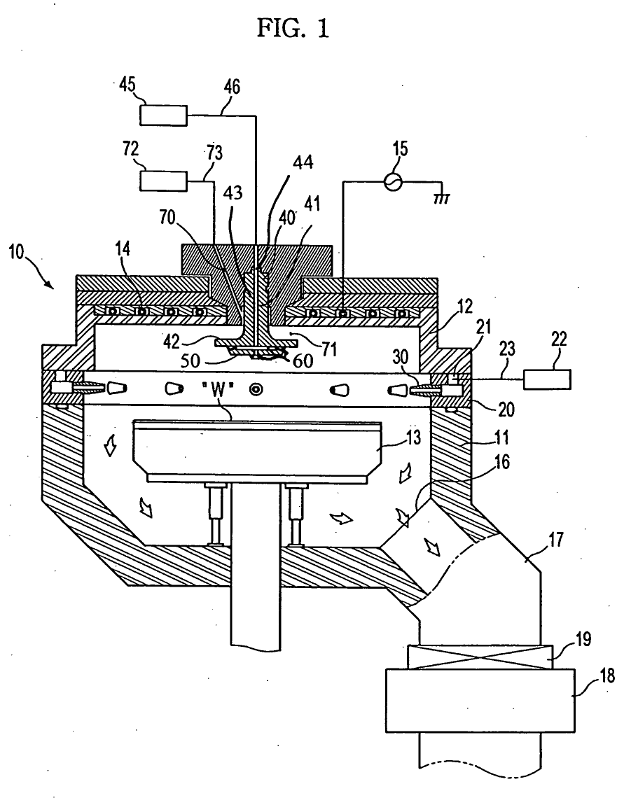

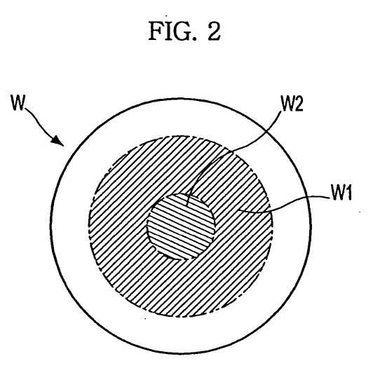

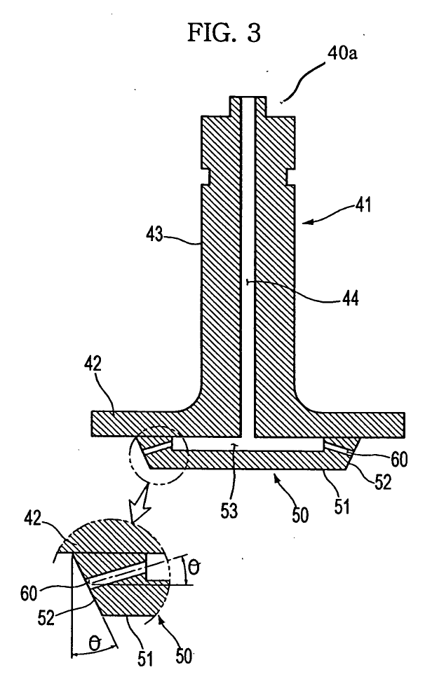

FIG. 1 is a cross-sectional view illustrating a high density plasma chemical vapor deposition apparatus according to the an embodiment of the present general inventive concept, and FIG. 2 is a schematic top view illustrating a semiconductor wafer W of FIG. 1. FIGS. 3 to 7 are cross-sectional views illustrating upper gas supply nozzles of the high density plasma chemical vapor deposition apparatus according to various embodiments of the present general inventive concept.

Referring to FIG. 1, a processing chamber 10 in which the semiconductor wafer W is processed includes a cylindrical chamber body 11 having an open upper portion, and a chamber cover 12 to cover the open upper portion of the chamber body 11. Herein, processes performed by the high density plasma chemical vapor deposition apparatus (which will be referred to as an “HDP CVD apparatus”) can include a deposition process of forming a thin film on the semiconductor wafer W, and an etching process of etching the thin film formed on the semiconductor wafer W to form a predetermined pattern thereon.

A chuck 13 is provided within the processing chamber 10 to support the semiconductor wafer W. The chuck 13 can be an electrostatic chuck which can hold the semiconductor wafer W by virtue of electrostatic force thereof. Bias power can be applied to the chuck 13 to induce a processing gas in a plasma state to migrate toward the semiconductor wafer W.

The chamber cover 12 is equipped at an upper portion thereof with an inductance coil 14 connected to a radio frequency (RF) power source 15 to generate an electromagnetic field to excite the processing gas supplied to the processing chamber 10 into the plasma state. The chamber cover 12 can be composed of an insulating material to which radio frequency energy is transmitted, and can be composed of aluminum oxide or a ceramic material.

A plurality of gas supply nozzles 30 and 40 are provided a lower end and an upper center of the chamber cover 12 to supply the processing gas into the processing chamber 10 so as to perform the deposition or etching process within the processing chamber 10.

A discharge port 16 is formed through a bottom portion of the chamber body 11 to discharge non-reactant processing gas and reactant by-products from the processing chamber 10. The discharge port 16 is connected to a discharge pipe 17 to which a vacuum pump 18 and a pressure controller 19 are connected to maintain a vacuum state within the processing chamber 10.

When performing the deposition process using the HDP CVD apparatus of FIG. 1, with the semiconductor wafer W held by the chuck 13 within the processing chamber 10, a processing gas for deposition is supplied into the processing chamber 10 through the plurality of gas supply nozzles 30 and 40. Then, the vacuum pump 18 and the pressure controller 19 are operated to maintain the processing chamber 10 in the vacuum state, and power is applied to the inductance coil 14 from the RF power source 15 to excite the processing gas into the plasma state. As a result, the processing gas is dissociated, followed by a chemical reaction thereof, so that a film is deposited on a surface of the semiconductor wafer W.

In order to uniformly perform the deposition process, the processing gas must be uniformly distributed over the semiconductor wafer W and have a high density. Accordingly, the HDP CVD apparatus of FIG. 1 includes a plurality of side gas supply nozzles 30 provided around a side of the processing chamber 10, and an upper gas supply nozzle 40 provided at an upper center portion of the chamber cover 12 to uniformly supply the processing gas to a reaction region above the semiconductor wafer W.

The plurality of side gas supply nozzles 30 can be uniformly spaced apart from each other within a circular gas distribution ring 20 coupled to a lower end of the chamber cover 12. The gas distribution ring 20 is formed with a gas guide groove 21 to supply the processing gas to the side gas supply nozzles 30, and the gas guide groove 21 can be connected to a first gas supply source 22 to supply a first processing gas via a pipe 23. This construction allows the first processing gas supplied from the first gas supply source 22 to be supplied into the processing chamber 10 through the plurality of side gas supply nozzles 30.

As illustrated in FIG. 2, the semiconductor wafer W includes a center region W2 and an intermediate region W1. The side gas supply nozzles 30 may be limited in uniformly supplying the processing gas to the center region W2 and the intermediate region W1 of the semiconductor wafer W. Accordingly, the upper gas supply nozzle 40 according to various embodiments of the present general inventive concept is capable of uniformly supplying the processing gas to the center region W2 and the intermediate region W1 of the semiconductor wafer W.

Referring to FIGS. 1-3, the upper gas supply nozzle 40 provided at the upper portion of the processing chamber 10 includes a nozzle body 41, a gas supply passage 44, a nozzle cover 50, and a plurality of gas inlets 60.

The nozzle body 41 includes a plate-shaped horizontal portion 42, and a vertical portion 43 extending from the horizontal portion 42 and fixed to an upper portion of the chamber cover 12. The horizontal portion 42 of the nozzle body 41 can have a flat disk shape.

The gas supply passage 44 can be vertically provided in the nozzle body 41 along an axis perpendicular to the semiconductor wafer W, and can be connected to a second gas supply source 45 to supply a second processing gas via a pipe 46.

The nozzle cover 50 is attached to a lower surface of the horizontal portion 42 of the nozzle body 41 and can be substantially parallel to the semiconductor wafer W. The nozzle cover 50 is formed with the plurality of gas inlets 60 through which the processing gas can be uniformly supplied towards the semiconductor wafer W within the processing chamber 10.

Referring to FIG. 3, the nozzle cover 50 of an upper gas supply nozzle 40a according to an embodiment of the present general inventive concept includes a horizontal cover bottom 51 and a cover side wall 52 extending at a predetermined angle with respect to the vertical direction from an edge of the cover bottom 51. The cover bottom 51 can have a disk shape, and thus, the nozzle cover 50 can have a frustoconical shape with an open upper portion. The nozzle cover 50 is attached to the lower surface of horizontal portion 42 of the nozzle body 41 such that a gas intake space 53 is defined by the cover side wall 52 between the lower surface of the horizontal portion 42 and the cover bottom 51, and communicates with the gas supply passage 44.

Meanwhile, the cover side wall 52 is formed with the plurality of gas inlets 60 in a circumferential direction to uniformly inject the second processing gas in a radial direction. Assuming that the cover side wall 52 is inclined at an angle of E with respect to the vertical direction, if the gas inlets 60 are perpendicular to a surface of the cover side wall 52, the gas inlets 60 supply the second processing gas to the semiconductor wafer W at an angle of θ with respect to the horizontal direction.

With the upper gas supply nozzle 40a constructed as illustrated in FIG. 3, the second processing gas supplied from the second gas supply source 45 flows into the gas intake space 53 through the gas supply passage 44 and is then supplied to the semiconductor wafer W through the gas inlets 60 formed in the cover side wall 52. Since the gas inlets 60 are formed in the cover side wall in the circumferential direction while being downwardly inclined to allow the second processing gas to be smoothly distributed, the second processing gas is uniformly distributed over the center region W2 and the intermediate region W1 of the semiconductor wafer W.

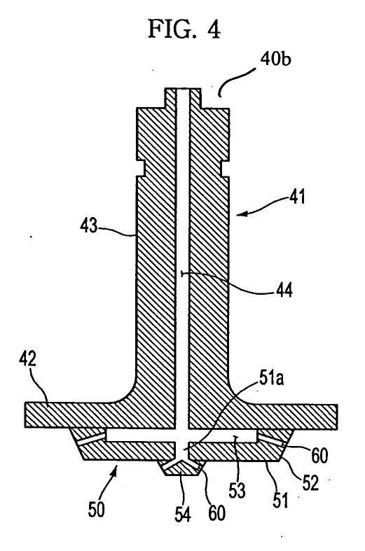

Referring to FIG. 4, an upper gas supply nozzle 40b according to another embodiment of the general inventive concept has similar construction to that of the upper gas supply nozzle 40a of the embodiment of FIG. 3 except for some construction as described below.

The upper gas supply nozzle 40b of FIG. 4 includes a nozzle cap 54 attached to a central lower surface of the cover bottom 51, which has a cover passage 51a passing through the cover bottom 51 so as to be coaxial with the gas supply passage 44. Similar to the nozzle cover 50, the nozzle cap 54 can have a frustoconical shape. The nozzle cap 54 includes a plurality of gas inlets 60 passing through a side wall thereof. The gas inlets 60 of the nozzle cap 54 are uniformly spaced in a circumferential direction, and communicate with the cover passage 51a.

After flowing from the second gas supply source 45 to the gas intake space 53 through the gas supply passage 44, the second processing gas is supplied to the semiconductor wafer W through the gas inlets 60 formed through the cover side wall 52 and the nozzle cap 54. As a result, the second processing gas is uniformly distributed over the center region W2 and the intermediate region W1 of the semiconductor wafer through the gas inlets formed through the nozzle cap 54 as well as the gas inlets 60 formed through the cover side wall 52, thereby enhancing uniform distribution of the reaction region.

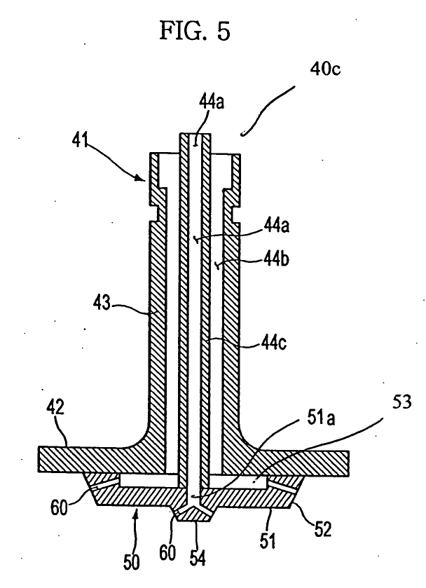

Referring to FIG. 5, an upper gas supply nozzle 40c according to another embodiment of the general inventive concept has similar construction to that of the upper gas supply nozzle 40b of the embodiment of FIG. 4 except for some construction as described below.

As illustrated in FIG. 5, the upper gas supply nozzle 40c includes a first gas supply passage 44a located along a center of the nozzle body 41 to supply the second processing gas towards the cover passage 51a, and a second gas supply passage 44b located around the first gas supply passage 44a to supply a third processing gas to the gas inlets 60 formed through the cover side wall 52 of the nozzle cover 50. Although not shown in FIG. 1, the second gas supply passage 44b can be connected to a third gas supply source to supply the third processing gas via a pipe. The first and second gas supply passages 44a and 44b are separated from each other by an intermediate member 44c provided between the first and second gas supply passages 44a and 44b. A lower end of the first gas supply passage 44a communicates with the cover passage 51a in the cover bottom 51, and a lower end of the second gas supply passage 44b communicates with the gas intake space 53 of the nozzle cover 50.

The second processing gas supplied through the first supply passage 44a is injected into the processing chamber 10 through the gas inlets 60 formed through the nozzle cap 54, and the third processing gas supplied through the second supply passage 44b is injected into the processing chamber 10 through the gas inlets 60 formed through the cover side wall 52. Since the second and third processing gases are separately supplied into the processing chamber 10, it is possible to control the second and third processing gases to be in an optimal state to deposit a uniform film on the semiconductor wafer W by independently controlling amounts of second and third processing gases when the second and third processing gases are supplied to the semiconductor wafer W. Additionally, various kinds of processing gas, such as silane or oxygen, can be supplied to the center region W2 and the intermediate region W1 of the semiconductor wafer W, thereby enhancing a stoichiometry of an oxide film deposition on the semiconductor wafer W.

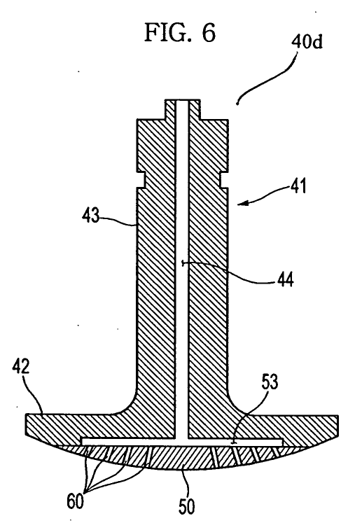

Referring to FIG. 6, the nozzle cover 50 of an upper gas supply nozzle 40d according to another embodiment of the present general inventive concept has a bottom surface with a convexly spherical shape, for example, a shower head shape. Moreover, the nozzle cover 50 has a plurality of rows of gas inlets 60 formed in a radial direction from a central axis of the nozzle cover 50 while being inclined with respect to the vertical direction.

The gas inlets 60 formed in the nozzle cover 50 may have diameters or angles which gradually increase as a distance from an associated gas inlet and the central axis of the nozzle cover 50 increases. For example, if a first row of the gas inlets 60 is spaced 10 mm from the central axis of the nozzle cover 50, a second row of the gas inlets 60 is spaced 15 mm from the central axis of the nozzle cover 50, and a third row of the gas inlets 60 is spaced 20 mm from the central axis of the nozzle cover 50, the first, second, and third rows of the gas inlets 60 may be inclined at angles of 15°, 20°, and 30°, respectively, with respect to the vertical direction, or may have diameters of 0.4 mm, 0.5 mm, and 0.6 mm, respectively. When the angle or the diameter of the gas inlets 60 is varied according to a location of the gas inlets 60, non-uniformity possibly caused by difference in positions of the gas inlets 60 formed through the nozzle cover 50 is relieved, thereby allowing the film to be uniformly deposited on the semiconductor wafer W.

As illustrated in FIG. 6, a lower surface of the horizontal portion 42 corresponding to a region where the gas inlets 60 are formed through the nozzle cover 50 is depressed by a predetermined depth, thereby defining a gas intake space 53 to distribute the second processing gas passing through the gas supply passage 44 to the gas inlets 60.

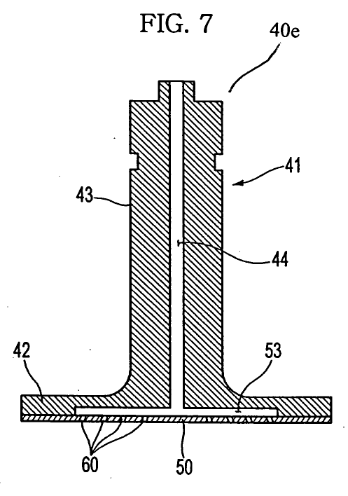

Referring to FIG. 7, an upper gas supply nozzle 40e according to another embodiment of the general inventive concept is substantially similar to the upper gas supply nozzle 40d of the embodiment of FIG. 6 except that the nozzle cover 50 of the upper gas supply nozzle 40e of FIG. 7 has a flat disk shape.

Returning to FIG. 1, the chamber cover 12 may further include a cleaning gas passage 70 formed around the upper gas supply nozzle 40 to supply a cleaning gas, such as NF₃, into the processing chamber 10. In this case, with the horizontal portion 42 of the nozzle body spaced a predetermined distance from the chamber cover 12 of the processing chamber 10, a vacuum channel 71 is formed between the horizontal portion 42 and the chamber cover 12 within the processing chamber 10 to communicate with the cleaning gas passage 70. Accordingly, the cleaning gas passing through the cleaning gas passage 70 is supplied into the processing chamber 10 after being refracted by the horizontal portion 42 of the chamber body, thereby effectively cleaning an inner surface of the processing chamber during a cleaning process. Meanwhile, the cleaning gas passage 70 can be connected to a cleaning gas supply source 72 to supply the cleaning gas via a pipe 73.

As described above, a process of depositing a film can be uniformly performed on a semiconductor wafer W by upper gas supply nozzles designed to uniformly distribute processing gas into a processing chamber according to various embodiments of the present general inventive concept.

Various embodiments of the present general inventive concept have advantageous effects of enhancing an overall uniformity by removing non-uniformity between an intermediate region of a semiconductor wafer deficient of processing gas supplied from side nozzles and other regions of the semiconductor wafer.

Moreover, since a larger size of semiconductor wafer causes more significant non-uniformity between the reaction regions, the above advantageous effects of the invention are effectively exhibited to a wafer having a diameter of 300 mm, thereby allowing the semiconductor manufacturing process to be more economically and effectively performed.

Although a few embodiments of the present general inventive concept have been shown and described, it would be appreciated by those skilled in the art that changes may be made in these embodiments without departing from the principles and spirit of the general inventive concept, the scope of which is defined in the claims and their equivalents.

What is claimed is:

1. A high density plasma chemical vapor deposition apparatus, comprising:
a processing chamber including a chamber body and a chamber cover; and
an upper gas supply nozzle provided at an upper portion of the processing chamber to supply a processing gas into the processing chamber, the upper gas supply nozzle comprising a nozzle body having a plate-shaped horizontal portion formed in a horizontal direction, a gas supply passage formed along the nozzle body in a vertical direction, a nozzle cover attached to a lower surface of the horizontal portion to form a passage therebetween, and a plurality of gas inlets formed on the nozzle cover to communicate with the passage and to uniformly supply the processing gas towards a semiconductor wafer within the processing chamber.

2. The apparatus according to claim 1, wherein the nozzle cover comprises a cover bottom and a conical cover side wall extending at a predetermined angle with respect to the vertical direction from the cover bottom, and the plurality of gas inlets is circumferentially formed on the conical cover side wall so as to radially inject the processing gas onto the semiconductor wafer.

3. The apparatus according to claim 2, wherein the upper gas supply nozzle further comprises a nozzle cap attached to a central lower surface of the nozzle cover, the cover bottom comprises a cover passage formed therein to communicate with one of the passage and the gas supply passage to be coaxial with the gas supply passage, and the nozzle cap comprises a plurality of second gas inlets inclined at a predetermined angle with respect to the horizontal direction while communicating with the cover passage.

4. The apparatus according to claim 3, wherein the gas supply passage comprises:
a first supply passage located along a central axis thereof to supply the processing gas to the cover passage;
a second supply passage disposed around the first supply passage to supply the processing gas to the gas inlets formed in the cover side wall through the passage; and
an intermediate member to separate the first and second supply passages.

5. The apparatus according to claim 1, wherein the nozzle cover comprises a bottom surface with a convexly spherical shape, and a plurality of rows of gas inlets inclined at a predetermined angle to the vertical direction while being provided in a radial direction from a central axis of the nozzle cover.

6. The apparatus according to claim 5, wherein the predetermined angles of the gas inlets inclined to the vertical direction are gradually increased as a distance from respective gas inlet and the central axis of the nozzle cover is increased

7. The apparatus according to claim 5, wherein diameters of the gas inlets are gradually increased as a distance from a respective gas inlet and the central axis of the nozzle cover is increased.

8. The apparatus according to claim 1, wherein the nozzle cover comprises a bottom surface with a flat disk shape, and comprises a plurality of rows of gas inlets inclined at a predetermined angle to the vertical direction while being provided in a radial direction from a central axis of the nozzle cover.

9. The apparatus according to claim 8, wherein the predetermined angles of the gas inlets inclined to the vertical direction are gradually increased as a distance from an associated gas inlet and the central axis of the nozzle cover is increased.

10. The apparatus according to claim 8, wherein diameters of the gas inlets are gradually increased as a distance from an associated gas inlet and the central axis of the nozzle cover is increased.

11. The apparatus according to claim 1, wherein:
the chamber cover comprises a cleaning gas passage formed around the upper gas supply nozzle to supply a cleaning gas into the processing chamber;
the horizontal portion of the nozzle body is spaced a predetermined distance from the chamber cover of the processing chamber such that a vacuum channel is formed between the horizontal portion and the chamber cover while communicating with the cleaning gas passage; and
the cleaning gas passing through the cleaning gas passage is supplied into the processing chamber after being refracted by the horizontal portion of the chamber body.

12. A semiconductor processing apparatus, comprising:
a reaction chamber to process a semiconductor wafer therein; and
a gas supplying nozzle disposed at an upper portion of the reaction chamber and comprising a first gas supplying passage disposed along a first axis perpendicular to the semiconductor wafer to supply a first process gas, and a plurality of gas inlets communicating with the first gas supplying passage and inclined at a predetermined angle with respect to the first axis to inject the first processing gas into the reaction chamber at the predetermined angle.

13. The semiconductor processing apparatus according to claim 12, wherein the plurality of gas inlets is provided around a circumference of a lower surface of the gas supplying nozzle, and the predetermined angle is not parallel or perpendicular to the semiconductor wafer.

14. The semiconductor processing apparatus according to claim 12, wherein the gas supplying nozzle further comprises a nozzle cover having an outer edge contacting a lower surface of the gas supplying nozzle and defining a gas intake space communicating with the first gas supplying passage, and the plurality of gas inlets is radially formed around the outer edge of the nozzle cover.

15. The semiconductor processing apparatus according to claim 12, wherein the gas supplying nozzle further comprises a gas intake space disposed at a lower end of the gas supplying nozzle perpendicular to the first gas supplying passage, and the plurality of inlets comprises a plurality of first inlets disposed at an outer portion of the gas intake space and a plurality of second inlet portions disposed at a lower end of the first gas supplying passage.

16. The semiconductor processing apparatus according to claim 12, wherein the gas supplying nozzle further comprises a second gas supplying passage disposed parallel to the first gas supplying passage to supply a second process gas, and a plurality of second gas inlets communicating with the second gas supplying passage and inclined at a second predetermined angle with respect to the first axis to inject the second supply gas into the reaction chamber.

17. The semiconductor processing apparatus according to claim 12, wherein the plurality of gas inlets comprises a plurality of concentric rows of gas inlets provided at a bottom surface of the gas supplying nozzle.

18. The semiconductor processing apparatus according to claim 12, wherein the plurality of gas inlets comprises:
a first circular row of gas inlets disposed adjacent to a bottom surface of the gas supplying unit at a first predetermined width; and
a second circular row of gas inlets separated from the gas supplying unit by the first circular row of gas inlets and disposed at a second predetermined width less than the first predetermined width.

19. A semiconductor processing apparatus comprising:
a reaction chamber to process a semiconductor therein; and
a gas supplying nozzle disposed at an upper portion of the reaction chamber and comprising a plurality of first gas inlets to inject a processing gas at a first predetermined angle with respect to a major plane of the semiconductor toward a first area of the semiconductor, and a plurality of second gas inlets to inject the processing gas at a second predetermined angle with respect to the major plane of the semiconductor toward a second area of the semiconductor disposed inside of the first area.

20. The semiconductor processing apparatus according to claim 19, further comprising:
a side gas supply nozzle disposed at a side portion of the reaction chamber to inject the processing gas toward the major plane of the semiconductor.
